(19) United States
(12) Patent Application Publication
(10) Pub. No.: US 2020/0019461 A1
(43) Pub. Date: Jan. 16, 2020

(54) MEMORY SYSTEM AND METHOD FOR READ OPERATION OF MEMORY SYSTEM

(71) Applicant: TOSHIBA MEMORY CORPORATION, Minato-ku (JP)

(72) Inventor: Yuki Sugiyama, Yokohama (JP)

(73) Assignee: TOSHIBA MEMORY CORPORATION, Minato-ku (JP)

(21) Appl. No.: 16/296,277

(22) Filed: Mar. 8, 2019

(30) Foreign Application Priority Data
Jul. 10, 2018 (JP) 2018-131082

(51) Int. Cl. G06F 11/10; G11C 16/04; G11C 16/26; G11C 16/10; G11C 16/14; G11C 29/52

(52) U.S. Cl. CPC G06F 11/1068; G11C 16/0483; G11C 16/26; H01L 27/11524; G11C 16/14; G11C 29/52; G11C 16/10

(57) ABSTRACT

According to one embodiment, a peripheral circuit of a first memory executes a read operation to acquire first data programmed to a first memory cell transistor of the first memory on the basis of a comparison between a threshold voltage of the first memory cell transistor and a determination voltage. An error corrector circuit corrects error in second data being the first data acquired by the read operation. When the error corrector circuit fails in the error correction in the second data, a memory controller acquires first history information, changes the determination voltage to a second voltage value in accordance with first history information, and causes the peripheral circuit to re-execute the read operation. The first history information includes second history information on elapsed time since the first data is programmed and third history information on the number of executed program operations on the first memory cell transistor.

### CROSS-REFERENCE TO RELATED APPLICATIONS

This application is based upon and claims the benefit of priority front Japanese Patent Application No. 2018-131082, filed on Jul. 10, 2018; the entire contents of which are incorporated herein by reference.

### FIELD

Embodiments described herein relate generally to a memory system and a method for a read operation of a memory system.

### BACKGROUND

Conventionally, memory systems including a memory cell transistor are known. In such a memory system, in read operation, data to be held in a memory cell transistor is determined on the basis of a comparison between a threshold voltage of the memory cell transistor and a determination voltage.

However, the threshold voltage of the memory cell transistor may vary depending on various factors. This may cause an erroneous determination of data, i.e., a bit error. As measures against a bit error, the memory system may be able to changeably set the value of the determination voltage. With occurrence of a bit error in read operation, the memory system can change the value of the determination voltage for retrying the read operation.

### BRIEF DESCRIPTION OF THE DRAWINGS

FIG. 1 is a diagram illustrating an exemplary configuration of a memory system according to a first embodiment;

FIG. 2 is a diagram illustrating an exemplary configuration of a memory chip of the first embodiment;

FIG. 3 is a diagram illustrating the circuit configuration of a block BLK of the first embodiment;

FIG. 4 is a cross-sectional view of a partial area of the block BLK of the first embodiment;

FIG. 5 is a diagram illustrating an exemplary possible threshold voltage of a memory cell of the first embodiment when executing a program in TLC mode;

FIG. 8 is a diagram for explaining data retention characteristics of a NAND flash memory;

FIG. 7 is a diagram illustrating an exemplary possible threshold voltage of the memory cell of the first embodiment when executing a program in SLC mode;

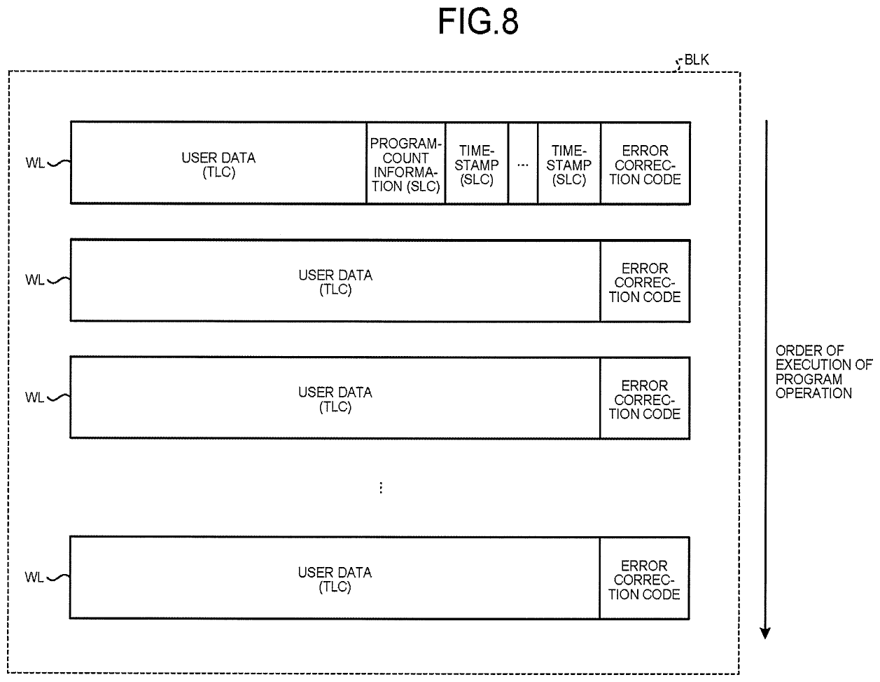

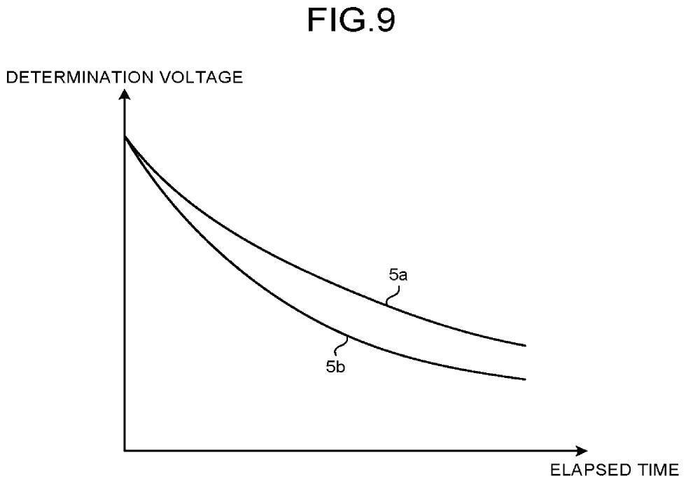

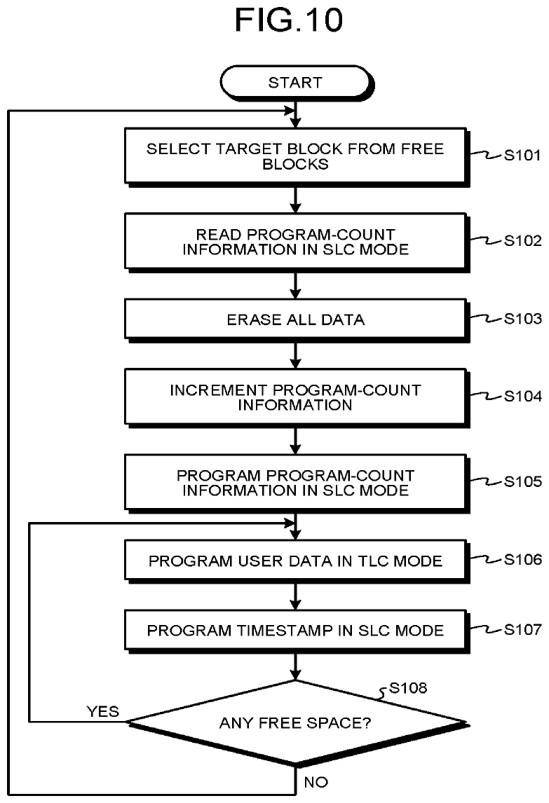

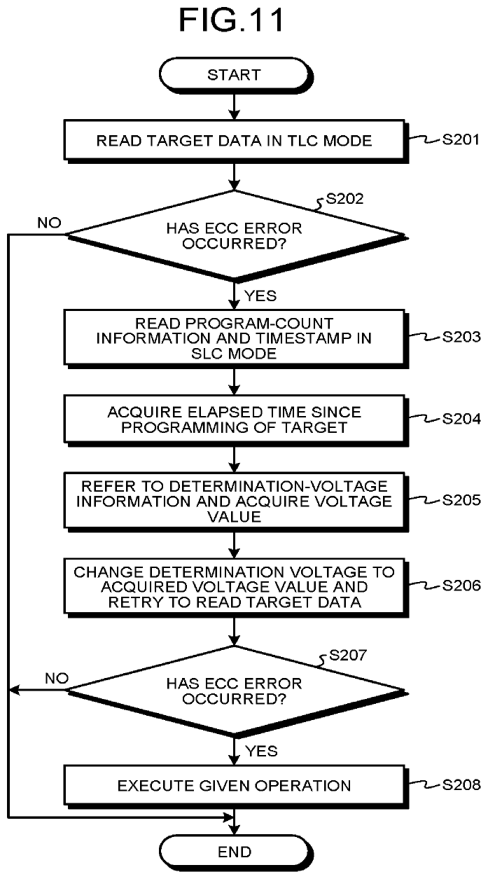

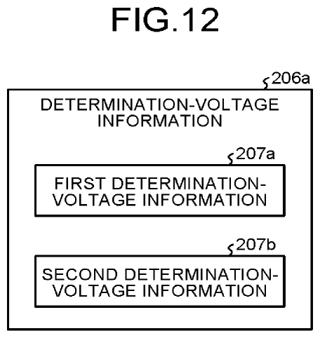

FIG. 8 is a diagram illustrating exemplary locations where program-count information and timestamps are programmed in the first embodiment;

FIG. 9 is a diagram illustrating an exemplary relationship among elapsed time, the number of executed program operations, and the determination threshold, the relationship being defined by determination-voltage information of the first embodiment;

FIG. 10 is a flowchart illustrating an exemplary data programming operation that is executed by the memory system of the first embodiment;

FIG. 11 is a flowchart illustrating an exemplary data read operation that is executed by the memory system of the first embodiment; and

FIG. 12 is a diagram illustrating an exemplary configuration of determination-voltage information of a second embodiment.

### DETAILED DESCRIPTION

In general, according to one embodiment, a memory system includes a first memory, an error corrector circuit, and a memory controller. The first memory includes a memory cell array and a peripheral circuit. The memory cell array includes a first memory cell transistor. The peripheral circuit executes a read operation to acquire first data programmed to the first memory cell transistor on the basis of a comparison between a threshold voltage of the first memory cell transistor and a determination voltage. The error corrector circuit corrects error in second data being the first data acquired by the read operation. When the error corrector circuit fails in the correction of the error in the second data, the memory controller acquires first history information, and changes the determination voltage from a first voltage value to a second voltage value in accordance with the first history information to cause the peripheral circuit to re-execute the read operation. The first history information includes second history information on an elapsed time from programming of the first data, and third history information on the number of executed program operations to the first memory cell transistor. The first voltage value is a set value resulting in the failure of the error correction of the second data.

Exemplary embodiments of a memory system and a method for read operation of a memory system will be described below in detail with reference to the accompanying drawings. These embodiments are merely exemplary and not intended to limit the present invention.

### First Embodiment

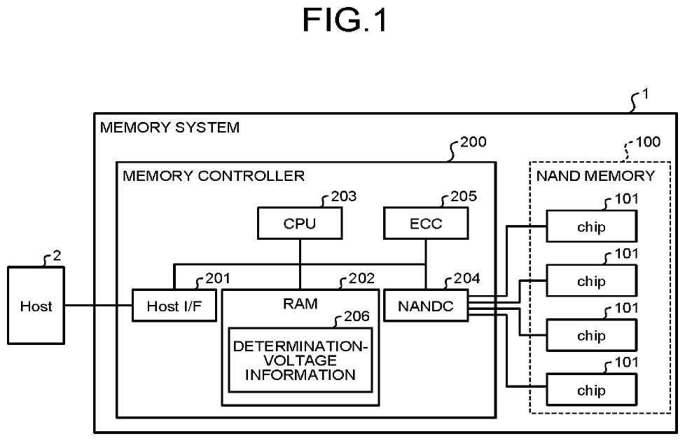

FIG. 1 is a diagram illustrating an exemplary configuration of a memory system of a first embodiment. A memory system 1 is connectable to a host (Host) 2. The host 2 represents, for example, a personal computer, a mobile information terminal, or a server. The memory system 1 functions as an external storage of the host 2.

The memory system 1 can receive access requests as a read request and a write request from the host 2. Each access request includes a logical address indicating an access destination. The logical address indicates a location in a logical address space provided by the memory system 1 to the host 2. The memory system 1 receives write target data together with a write request.

The memory system 1 includes a NAND flash memory (NAND memory) 100, and a memory controller 200 that transfers data between the host 2 and the NAND memory 100.

The NAND memory 100 includes one or more memory chips (CHIP) 101. Herein, the NAND memory 100 includes four memory chips 101, as an example.

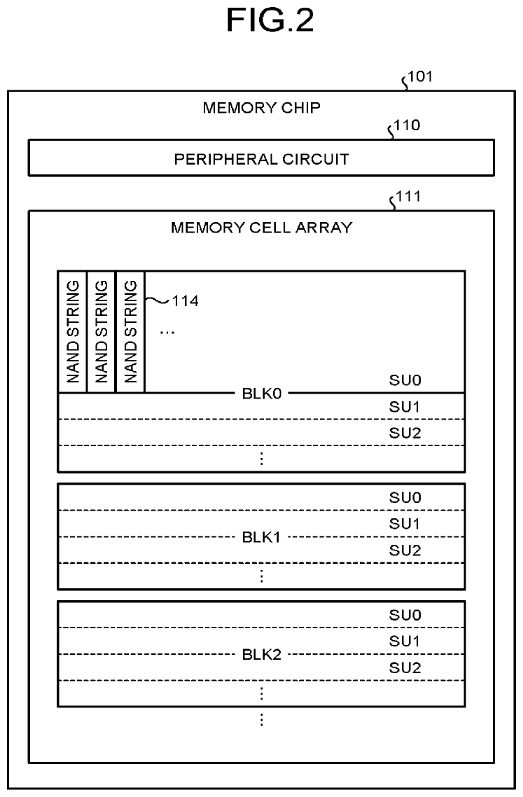

FIG. 2 is a diagram illustrating an exemplary configuration of the memory chip 101 of the first embodiment. As illustrated, the memory chip 101 includes a peripheral circuit 110 and a memory cell array 111.

The memory cell array 111 includes a plurality of blocks BLK (BLK0, BLK1, . . . ) each being a set of nonvolatile memory cell transistors. Each of the blocks BLK includes a plurality of string units SU (SU0, SU1, . . . ) each being a set of memory cell transistors associated with a word line and a bit line. Each of the string units SU includes a plurality of NAND strings 114 in which the memory cell transistors are connected in series. The number of the NAND strings 114 in the string unit SU is freely set.

The peripheral circuit 110 includes, for example, a row decoder, a column decoder, a sense amplifier, a latch circuit, and a voltage generator circuit. When receiving a command from the memory controller 200, the peripheral circuit 110 executes one of a program operation, a read operation, and an erase operation to the memory cell array 111 in accordance with the command.

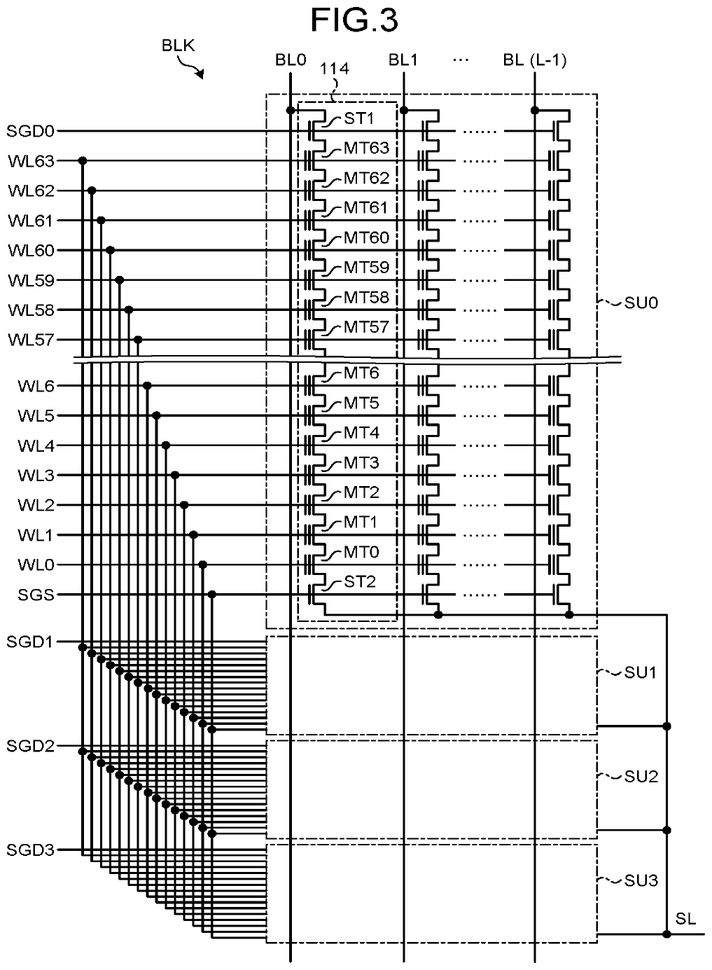

FIG. 3 is a diagram illustrating the circuit configuration of the block BLK of the first embodiment. The blocks BLK have the same configuration. The block BLK includes, for example, four string units SU0 to SU3. The string unit SU includes the NAND strings 114.

Each of the NAND strings 114 includes, for example, 64 memory cell transistors MT (MT0 to MT63) and select transistors ST1 and ST2. Each memory cell transistor MT includes a control gate and a charge storage layer, and holds data in a nonvolatile manner. The 64 memory cell transistors MT (MT0 to MT63) are connected in series between a source of the select transistor ST1 and drain of the select transistor ST2. The memory cell transistors MT may be of a MONOS type including an insulating film for the charge storage layer or may be of a FG type including a conductive film for the charge storage layer. The number of the memory cell transistors MT in the NAND string 114 is not limited to 64.

Gates of the select transistors ST1 in the string units SU0 to SU3 are connected to select gate lines SGD0 to SGD3, respectively. In contrast, gates of the select transistors ST2 in the string units SU0 to SU3 are connected in common to, for example, a select gate line SGS. The gates of the select transistors ST2 in the string units SU0 to SU3 may be connected to different select gate lines SGS0 to SGS3 in the string units SU. The control gates of the memory cell transistors MT0 to MT63 in the same block BLK are connected in common to word lines WL0 to WL63, respectively.

Drains of the select transistors ST1 of the NAND strings 114 in the string units SU are connected to different bit lines BL (BL0 to BL(L−1) where L represents a natural number of two or greater), respectively. Each bit line BL connects one NAND string 114 in each string unit SU in common across the blocks BLK. A source of each select transistor ST2 is connected in common to a source line SL.

In other words, the string unit SU is a set of the NAND strings 114 that are connected to different bit lines BL and to the same select gate line SGD. The block BLK is a set of the string units SU having the common word lines WL. The memory cell array 111 is a set of the blocks BLK connected in common to the bit lines BL.

The peripheral circuit 110 can collectively execute a program operation and a read operation to all the memory cell transistors MT connected to one word line WL in one string unit SU. An aggregate of one-bit data subjected to the program operation or read operation on one word line WL in one string unit SU is expressed as a page.

The peripheral circuit 110 executes erase operation in units of the blocks BLK. In other words, all the data stored in one block BLK is erased at a time.

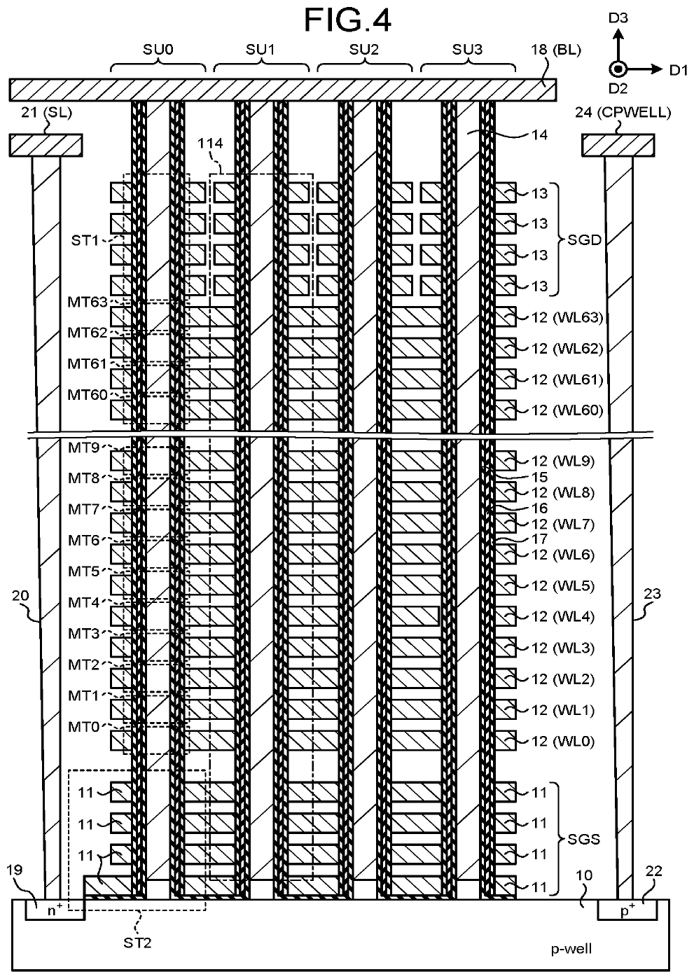

FIG. 4 is a cross-sectional view of a partial area of the block BLK of the first embodiment. As illustrated in FIG. 4, the NAND strings 114 are arranged above a p-well region 10. In other words, for example, four wiring layers 11 functioning as the select gate lines SGS, 64 wiring layers 12 functioning as the word lines WL0 to WL63, and four wiring layers 13 functioning as the select gate lines SGD are sequentially placed on the top of each other above the well region 10. Not-illustrated insulating films are formed between the wiring layers.

A pillared conductor 14 reaches the well region 10 through the wiring layers 13, 12, and 11. The conductor 14 includes, on a side surface, a gate insulating film 15, a charge storage layer (insulating or conductive film) 16, and a block insulating film 17 sequentially. The films form the memory cell transistors MT and the select transistors ST1 and ST2. The conductor 14 functions as a current path in the NAND string 114 and serve as a region in which the channels of the transistors are formed. The conductor 14 is connected to the top end of a metal wiring layer 18 functioning as the bit line BL.

The well region 10 includes an n+ impurity diffusion layer 19 on a surface area. A contact plug 20 is formed on the diffusion layer 19 and connected to a metal wiring layer 21 functioning as the source line SL. The well region 10 includes a p+ impurity diffusion layer 22 on a surface area. A contact plug 23 is formed on the diffusion layer 22 and connected to a metal wiring layer 24 functioning as a well wire CPWELL. The well wire CPWELL refers to a wire for applying a potential to the conductor 14 via the well region 10.

The above configurations are aligned in a second direction D2 parallel to a semiconductor substrate. A set of the NAND strings 114 aligned in the second direction D2 constitutes the string unit SU.

The configurations illustrated in FIGS. 2 to 4 are merely exemplary. The configuration of the memory cell array 111 is not limited to the above configurations. For example, the memory cell array 111 may include two-dimensionally arranged NAND strings 114.

Hereinafter, the memory cell transistor MT is simply expressed as a memory cell.

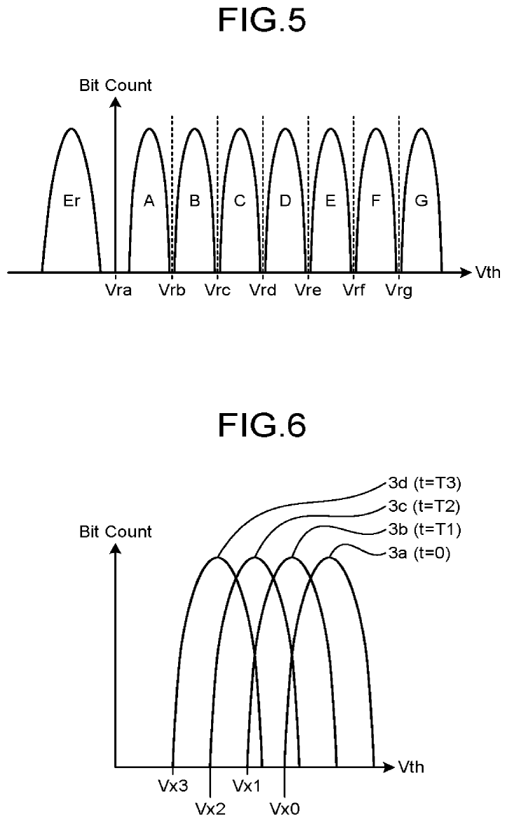

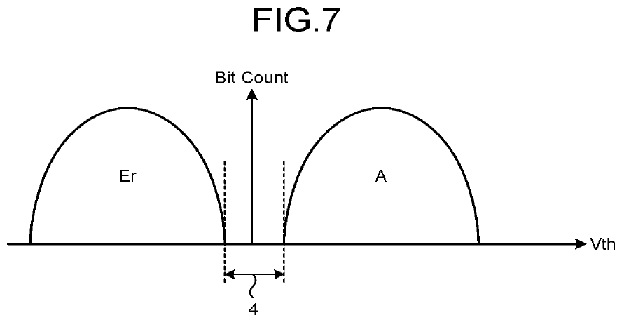

FIG. 5 is a diagram illustrating an exemplary possible threshold voltage of the memory cell of the first embodiment. The vertical axis indicates the number of memory cells, i.e., bit count, and the horizontal axis indicates the threshold voltage (Vth). FIG. 5 illustrates the threshold voltage when data is programmed in a triple level cell (TLC) mode in which each memory cell holds three-bit data.

In the TLC mode, a possible threshold voltage range is divided into eight ranges as illustrated in FIG. 5. The eight ranges are referred to as state “Er”, state “A”, state “B”, state “C”, state “D”, state “E”, state “F”, and state “G”, in order from the lowest threshold voltage. In the program operation, the peripheral circuit 110 controls the threshold voltage of each memory cell to be included in any of state “Er”, state “A”, state “B”, state “C”, state “D”, state “E”, state “F”, and state “G”.

As a result, when the number of memory cells with respect to the threshold voltage is plotted, the memory cells form eight distributions that belong to different states, as illustrated in FIG. 5.

The eight states correspond to different three-bit data. As an example, state “Er” corresponds to “111”, state “A” corresponds to “110”, state “B” corresponds to “100”, state “C” corresponds to “000”, state “D” corresponds to “010”, state “E” corresponds to “011”, state “F” corresponds to “001”, and state “G” corresponds to “101”. Thus, each memory cell can hold data corresponding to the state of a threshold voltage of the memory cell.

Each digit of three-bit data held in one memory cell is expressed by a term representing the location of the digit. For example, least significant bit (LSB) is referred to as lower bit, most significant bit (MSB) is referred to as upper bit, and the bit between LSB and MSB is referred to as middle bit. A set of lower bits of all memory cells belonging to the same word line is expressed as a lower page. A set of middle bits of all memory cells belonging to the same word line is expressed as a middle page. A set of upper bits of all memory cells belonging to the same word line is expressed as an upper page.

Through the erase operation, the threshold voltage falls to state “Er”. Through the program operation, the threshold voltage is maintained in state “Er”, or rises to any of state “A”, state “B”, state “C”, state “D”, state “E”, state “F”, and state “G”.

A determination voltage is set between every two adjacent states. For example, as illustrated in FIG. 5, a determination voltage Vra is set between states “Er” and “A”, a determination voltage Vrb is set between states “A” and “B”, a determination voltage Vrc is set between states “B” and “C”, a determination voltage Vrd is set between states “C” and “D”, a determination voltage Vre is set between states “D” and “E”, a determination voltage Vrf is set between states “E” and “F”, and a determination voltage Vrg is set between states “F” and “G”. In other words, in TLC mode in which the eight states are set, the seven determination voltages are set. In the read operation, the peripheral circuit 110 determines the state of each memory cell in accordance with the determination voltages, and decodes the determined state into data.

In a memory cell in which data is programmed, electrons stored in the charge storage layer 16 are detrapped, lowering the threshold voltage depending on the elapsed time from programming of the data into the memory cell. This phenomenon is known as the data retention characteristics of a NAND flash memory.

FIG. 6 is a diagram illustrating the data retention characteristics of a NAND flash memory. FIG. 6 illustrates temporal changes in one of the eight distributions excluding the distribution of state “Er” in FIG. 5.

As illustrated in FIG. 6, a distribution 3a of memory cells immediately after data programming (t=0) does not extend across a voltage value Vx0. Hence, in this state, setting the voltage value Vx0 as the determination voltage enables accurate reading of the data corresponding to the distribution 3a.

However, with elapse of time since the data programming as T1, T2, and T3 (0<T1<T2<T3), the threshold voltage of each memory cell decreases, shifting the distribution 3a of the threshold voltage to 3b, 3c, and 3d on the negative side.

Hence, when, for example, the determination voltage takes the voltage value Vx0 at t=T1, T2, and T3, part or whole of the threshold-voltage distribution exceeds the determination voltages on the boundaries between the states. This may cause erroneous determination of data. In other words, different bit data from programmed bit data is read, which may cause a bit error.

In order to prevent a bit error, the determination voltage needs to be varied in accordance with a variation in the threshold-voltage distribution. In the example of FIG. 6, shifting the determination voltage to Vx1, Vx2, and Vx3 with elapse of time since the data programming as T1, T2, and T3 can prevent a bit error arising from the data retention characteristics.

The data retention characteristics of memory cells may be affected by the number of executed program operations to the memory cells. In a NAND flash memory, a data programmed block is subjected to the erase operation to erase all the data at a time, and then becomes data programmable again. Hence, the number of executed program operations can also translate to the number of executed program and erase cycles, or the number of executed erase operations. The number of executed program operations may be regarded as the same among the memory cells in each block.

The program operation applies stress to the memory cells. Along with an increase in the number of the executed program operations, electrons stored on the charge storage layer 16 of the memory cell is more likely to be detrapped. This result in increasing the change rate of the threshold voltage due to the data retention characteristics. That is, with the increase in the number of executed program operations to a certain block, the time taken for the memory cells of the block to make a bit error from the data programming shortens.

As described above, the threshold-voltage distribution changes depending on various factors. A bit error occurs or the number of bit errors increases due to the change in the threshold-voltage distribution.

Memory systems incorporating NAND flash memories typically include an error correction function. Data garbled by a bit error is corrected to correct data by the error correction function. However, if the bit error count or rate exceeds the performance of the error correction function, the memory system cannot acquire correct data, failing in the read operation.

In a method as a comparison with the first embodiment, for example, different candidate values of the determination voltage are prepared. With a failure of the read operation, the memory controller repeatedly retries the read operation, i.e., retry read operation while setting the candidate values as the determination voltage in a given order. However, such a comparative method may require a large number of retry read operations before succeeding in the read operation, which deteriorates the performance, particularly read latency, by the number of repetitions of the retry read operation.

In the first embodiment, the memory controller 200 stores, in advance, information, as determination-voltage information 206 of FIG. 1, representing the correspondence among the elapsed time since programming of data into a memory cell (which hereinafter may be simply expressed as elapsed time), the number of the executed program operations to the memory cell, and an estimated value of the determination voltage that enables prevention of a bit error. In the retry read operation, the memory controller 200 acquires the elapsed time and the number of executed program operations of a memory cell at a reading location, as history information of the memory cell. The memory controller 200 then acquires a voltage value corresponding to the history information as a new set value of the determination voltage, with reference to the determination-voltage information 206, and changes or shifts the determination voltage from the current set value to the new set value.

The memory controller 200 as configured above can acquire correct data through a single retry read operation after failing in the read operation. In other words, according to the first embodiment, the memory controller 200 can prevent deterioration of performance as compared with by the comparative method.

The memory controller 200 records in advance the number of executed program operations and the data programming time, i.e., timestamp, in the NAND memory 100. When acquiring a new set value of the determination voltage, the memory controller 200 acquires the number of executed program operations and the elapsed time since data programming, from the record in the NAND memory 100.

The memory controller 200 programs the number of executed program operations and a timestamp in the NAND memory 100 in single level cell (SLC) mode. The SLC mode is a mode in which each memory cell holds one-bit data.

FIG. 7 is a diagram illustrating an exemplary possible threshold voltage of the memory cell at the time of data programming in SLC mode in the first embodiment. The vertical axis indicates the number of memory cells, that is, a bit count, and the horizontal axis indicates the threshold voltage.

In the TLC mode, a possible threshold voltage range is divided into eight ranges, as illustrated in FIG. 5. In the SLC mode, a possible threshold voltage range is divided into two ranges, state “Er” and state “A” as illustrated in FIG. 7. In the program operation, the peripheral circuit 110 controls the threshold voltage of each memory cell to be maintained in state “Er” or included in state “A”. State “Er” is associated with “0” or “1”, and state “A” is associated with a value different from the value associated with state “Er”, “0” or “1”. Thereby, each memory cell can hold one-bit data.

Each state can occupy a wider area in SLC mode than in TLC mode. That is, it is easier to control the threshold voltage in SLC mode than in TLC mode. Hence, the SLC mode enables a decrease in the time taken for the program operation as compared with the TLC mode. Moreover, the SLC mode allows a sufficient margin (margin 4 in FIG. 7) between the distribution in state “Er” and the distribution in state “A”. This makes it possible to improve tolerance to a variation in the threshold voltage, that is, data reliability, as compared with the TLC mode.

In the first embodiment, the memory controller 200 programs user data from the host 2 in TLC mode, and programs the number of executed program operation and a timestamp in SLC mode. Thereby, the memory controller 200 can prevent a failure in the read operation of the number of executed program operations and a timestamp, even in a situation that the read operation of user data fails.

In the first embodiment, the number of executed program operations is counted and recorded on a block by block basis, as an example. Timestamps are recorded in units of a word line. The unit of counting the executed program operations and the unit of recording timestamps are not limited to such units.

The number of executed program operations recorded in the NAND memory 100 is expressed as program-count information below.

FIG. 8 is a diagram illustrating exemplary locations where program-count information and timestamps are programmed in the first embodiment. As illustrated in FIG. 8, the program-count information and timestamps are programmed into the top word line of each block. The top word line of a block refers to a word line assigned with a physical address of the smallest number in the block, and the top word line is generally the first one to be subjected to the program operation in the block. The order of physical addresses may or may not correspond to the physical arrangement of the word lines.

Firstly, program-count information is programmed at a certain location of the top word line of the block. Upon execution of the program operation to the second and subsequent word lines in the same block, timestamps are sequentially programmed at locations following the location where the program-count information has been programmed. The order of storage locations of the timestamps corresponds to the arrangement of the word lines. This makes it possible to identify a location of a programmed timestamp indicating the time when data is written into a word line.

Program-count information and timestamps are programmed in SLC mode as described above. User data is programmed in TLC mode.

An error correction code, which is generated from data such as program-count information, a timestamp, or user data, programmed at a preceding location, is programmed at the end of the word line.

In this manner, program-count information, timestamps of each word line, and an error correction code are stored in a location subsequent to a certain location of the top word line of a block. The area before the storage location of the program-count information of the top word line of the block is used for storing user data. User data can also be programmed into the top word line of the block in TLC mode.

The locations where program-count information and timestamps are programmed are not limited to the locations illustrated in FIG. 8. The locations where program-count information and timestamps are programmed may be variously changed depending on the recording timings and units of program-count information and timestamps.

Program-count information and timestamps may be, for example, programmed into the last word line of each block. The last word line refers to a word line assigned with a physical address of the largest number in a block. For example, program-count information and timestamps concerning a certain block are held in a volatile storage area as a RAM 202 of FIG. 1, for example. Upon completion of the program operation of user data to the word line one prior to the last word line of the block, the program-count information and the timestamps are transferred from the volatile storage area to the last word line of the block.

Returning to FIG. 1, the memory controller 200 includes a host interface (Host I/F) 201, the random access memory (RAM) 202, a central processing unit (CPU) 203, a NANDC 204, and an error corrector circuit (ECC) 205.

The memory controller 200 may be configured as, for example, an SoC (System-On-a-Chip). The memory controller 200 may include a plurality of chips. The memory controller 200 may include a field-programmable gate array (FPGA) or an application specific integrated circuit (ASIC) instead of the CPU 203. In other words, the memory controller 200 may be configured by software, hardware, or a combination of both.

The RAM 202 represents a buffer or a memory for use as a work area of the CPU 203. The memory type of the RAM 202 is not limited to a specific type. For example, the RAM 202 includes a dynamic random access memory (DRAM), a static random access memory (SRAM), or a combination of both.

The RAM 202 stores the determination-voltage information 206. The determination-voltage information 206 refers to information for defining the correspondence among the elapsed time, the number of executed program operations, and the determination voltage, as described above.

FIG. 9 is a diagram illustrating an exemplary relationship, defined by the determination-voltage information 206, among the elapsed time, the number of executed program operations, and the determination voltage. In reality, the determination-voltage information 206 is prepared for all the seven determination voltages Vra to Vrg. For the sake of simple explanation, FIG. 9 illustrates one item among the determination-voltage information 206 prepared for Vra to Vrg.

As illustrated in FIG. 9, the determination voltage, set for preventing a bit error, decreases in accordance with elapse of the time since the completion of programming. With a larger number of program operations executed, the decrease rate of the determination voltage with respect to the elapsed time increases as compared with a smaller number of program operations executed.

With a smaller number of executed program operations, for example, the memory controller 200 adopts a relationship specified by a curve 5a. With a smaller number of executed program operations, the memory controller 200 adopts a relationship specified by a curve 5b. The curve 5b shows a higher decrease rate of the determination voltage with respect to the elapsed time than the curve 5a.

The determination-voltage information 206 is obtained in advance through experiment or calculation, and is stored in a nonvolatile storage area (for example, the NAND memory 100). At startup of the memory system 1, for example, the CPU 205 loads the determination-voltage information 206 into the RAM 202 for usage.

The determination-voltage information 206 may be stored in the NAND memory 100 and provided for the CPU 203 to use.

The data structure of the determination-voltage information 206 is not limited to a specific data structure. The determination-voltage information 206 may be prepared as a table, a mathematical formula, or data of a combination thereof. The determination-voltage information 206 may be incorporated as a conditional branch syntax or a mathematical formula in a firmware program. The determination-voltage information 206 may be prepared as discrete data or continuous data. The determination-voltage information 206 may be prepared as a hierarchical table group.

The relationship among the elapsed time, the number of executed program operations, and the determination voltage, as illustrated in FIG. 9, is merely exemplary. The relationship among the elapsed time, the number of executed program operations, and the determination voltage is freely defined by the determination-voltage information 206.

Returning again to FIG. 1, the host interface 201 controls a communication interface with the host 2. The host interface 201 transfers data between the host 2 and the RAM 202 under the control of the CPU 203. The NANDC 204 transfers data between the NAND memory 100 and the RAM 202 under the control of the CPU 203.

The CPU 203 controls the host interface 201, the RAM 202, the NANDC 204, and the ECC 205. The CPU 203 executes a firmware program pre-stored in a nonvolatile storage area (for example, the NAND memory 100) to implement control over the above various elements.

The ECC 205 is an exemplary error corrector circuit. The ECC 205 codes data, as the number of executed program operations, a timestamp, or user data, to be transmitted to the NAND memory 100. Coding is coding with an error correction code. The ECC 205 decodes the data sent from the NAND memory 100 to detect and correct a bit error. Having failed to correct a bit error, the ECC 205 notifies the CPU 203 of the failure.

A coding method used by the ECC 205 is not limited to a specific method. As an example, the ECC 205 may employ a low density parity check (LDPC) as the coding method.

The size of a data block being the unit of coding and decoding by the ECC 205 is not limited to a specific size. As an example, the ECC 205 performs coding and decoding per page. An error correction code generated by coding is programmed, for example, at the end of each word line (refer to FIG. 8).

Next, the operation of the memory system 1 of the first embodiment is described referring to FIGS. 10 and 11.

FIG. 10 is a flowchart illustrating an exemplary data programming operation that is executed by the memory system 1 of the first embodiment.

Firstly, the memory controller 200 sets a block to be a write destination. Specifically, the memory controller 200 (for example, the CPU 203) selects a block from free blocks as a data write destination (S101).

Free blocks refer to blocks in which all the written user data have been invalidated. A free block is generated by a transcription. The transcription includes garbage collection and wear leveling.

Garbage collection refers to an operation for transcribing valid data in the data stored in a certain block (as a first block) to another block (as a second block), and then regarding all the data stored in the first block as invalid. Garbage collection makes the first block a free block.

Wear leveling refers to an operation for transcribing data among the blocks to level the numbers of executed program operations among the blocks. A block being a source of data transcription by wear leveling becomes a free block after the data transcription.

Free blocks are registered in a free block pool for management purpose. The memory controller 200 selects a target block from one or more blocks registered in the free block pool.

The block selected in S101 is referred to as a target block in FIG. 10. The memory chip 101 including the target block is referred to as a target memory chip 101.

After S101, the memory controller 200 reads program-count information from the target block in SLC mode (S102).

For example, the memory controller 200 transmits, to a target memory chip 101, a read command including an instruction on a storage location of program-count information and an instruction on the SLC mode. The storage location of the program-count information is set to a certain location around the middle of the top word line of the target block in the example of FIG. 8. The peripheral circuit 110 executes a read operation in SLC mode at the instructed location in the target memory chip 101 in response to the read command. Thereby, the peripheral it 110 acquires the program-count information. The peripheral circuit 110 sends the acquired program-count information to the memory controller 200.

Subsequent to S102, the memory controller 200 erases all the data stored in the target block (S103).

For example, the memory controller 200 transmits, to the target memory chip 101, an erase command including an instruction on the target block. The peripheral circuit 110 executes the erase operation to the target block of the target memory chip 101 in response to the erase command. Thereby, the threshold voltage of each memory cell of the target block falls to state Er and the target block now stores no data.

Subsequent to S103, the memory controller 200 increments the program-count information by one (S104). The memory controller 200 then programs the incremented program-count information into the target block in SLC mode (S105).

For example, the memory controller 200 transmits, to the target memory chip 101, a program command including program-count information, an instruction on a storage location of the program-count information, and an instruction on the SLC mode. In the example of FIG. 8, the storage location of the program-count information is set to a certain location around the middle of the top word line of the target block. The peripheral circuit 110 executes a program operation to the instructed location of the target memory chip 101 in SLC mode in response to the program command, to program the program-count information.

Thus, through the operation in S102 to S105, the number of executed program operations to the target block is counted and recorded.

Subsequent to S105, the memory controller 200 programs user data into the target block in TLC mode (S106).

For example, the memory controller 200 transmits, to the target memory chip 101, a program command including user data, an instruction on a storage location of the user data, and an instruction on the TLC mode. The peripheral circuit 110 executes the program operation to the instructed location of the target memory chip 101 in TLC mode in response to the program command, to program the user data.

Subsequent to S106, the memory controller 200 programs a timestamp in SLC mode (S107). In S107, for example, a timestamp is programmed as in S105.

The unit of executing the operation in S106 and the operation in S107 is not limited to a particular unit. For example, the operation in S106 may be executed on one word line, and the operation in S107 may be executed immediately after S106. The operation in S106 may be continuously executed on two or more word lines, and the operation in S107 may be executed immediately after S106, corresponding to the operation to the word lines in S106.

Subsequent to S107, the memory controller 200 determines whether or not the target block includes a free space (S108). The free space refers to a word line on which user data is programmable.

If a free space is found (YES in S108), the memory controller 200 transitions to S106. If the target block includes no free space (NO in S108), the memory controller 200 transitions to S101.

Thus, according to the example of FIG. 10, the number of executed program operations on a memory cell is counted and recorded in units of block. A timestamp indicating the time when data is programmed into a memory cell is recorded in units of word line. The units execution of the operations are not limited to them. For example, a timestamp indicating the time when data is programmed into a memory cell may be recorded in units of block.

FIG. 11 is a flowchart illustrating an exemplary data read operation that is executed by the memory system 1 of the first embodiment. In FIG. 11, user data to be read is referred to as target data. Moreover, a block containing the target data is referred to as a target block. The memory chip 101 including the target block is referred to as a target memory chip 101.

Firstly, the memory controller 200 reads target data as user data from the target block in TLC mode (S201).

For example, the memory controller 200 transmits, to the target memory chip 101, a read command including an instruction on a storage location of the target data and an instruction on the TLC mode. The peripheral circuit 110 executes a read operation to the instructed location of the target memory chip 101 in TLC mode in response to the read command. Thereby, the peripheral circuit 110 acquires the target data. At this point, however, the target data may include a bit error. The peripheral circuit 110 sends the acquired target data to the memory controller 200.

In S201, the determination voltages Vra to Vrg are set to given voltage values. For example, the determination voltages Vra to Vrg may take preset initial values. Alternatively, when the retry read operation has been executed to the same word line or a nearby word line before, in S201 the determination voltages Vra to Vrg may be set to the determination voltage values used in the retry read operation.

Next, the memory controller 200 determines whether or not an ECC error has occurred (S202).

The ECC 205 detects and corrects a bit error in the target data acquired in S201. The ECC error refers to a failure of the ECC 205 in the correction of a bit error. Upon failing to correct a bit error in the target data, the ECC 205 notifies the CPU 203 of the failure. Thereby, the CPU 203 can find the occurrence of the ECC error.

With occurrence of an ECC error (YES in S202), the memory controller 200 reads program-count information and a timestamp from the target block in SLC mode (S203). In S203, for example, the memory controller 200 reads them as in S102.

Subsequent to S203, the memory controller 200 acquires the elapsed time since the target data is programmed, from the timestamp (S204). The memory controller 200 can compute the elapsed time by subtracting the time recorded as the timestamp from the current time.

Subsequent to S204, the memory controller 200 refers to the determination-voltage information 206 to acquire a voltage value corresponding to the elapsed time and the number of executed program operations (S205).

Subsequent to S205, the memory controller 200 changes the determination voltage from the voltage value set in S201 to the voltage value acquired in S204, and retries to read the target data (S206).

For example, the memory controller 200 transmits, to the target memory chip 101, a read command including a new set value of the determination voltage, an instruction on a storage location of the target data, and an instruction on the TLC mode. The peripheral circuit 110 executes the read operation i.e., retry read operation to the instructed location of the target memory chip 101 in TLC mode in response to the read command, using the new set value of the determination voltage. Thereby, the peripheral circuit 110 acquires the target data. The peripheral circuit 110 sends the acquired target data to the memory controller 200.

The ECC 205 detects and corrects a bit error in the target data acquired in S206. The memory controller 200 determines whether or not an ECC error has occurred (S207).

With occurrence of an ECC error (YES in S207), the memory controller 200 executes a given operation (S208), completing the operation for reading the target data.

The given operation can be freely set.

As an example, different candidate values of the determination voltage are prepared in addition to the determination-voltage information 206. The memory controller 200 may repeat the retry read operation, using the different candidate values as the determination voltage in predetermined order.

The memory controller 200, if including a second error correction function higher in error correctability than the ECC 205, may try to correct a bit error in the target data acquired in S201 or S205 with the second error correction function.

Alternatively, the memory controller 200 may notify the host 2 of the target data being non-correctable.

If an ECC error has not occurred (NO in S202 and S207), the memory controller 200 ends the operation for reading the target data.

The operation for reading can include not only a data read from the NAND memory 100 in response to a read request of the host 2 but also a data read being part of the transcription operation, i.e., garbage collection or wear leveling. In the operation for reading in response to a read request from the host 2, the memory controller 200 transfers the target data to the host 2 via the RAM 202.

As described above, according to the first embodiment, having failed in the error correction to the target data acquired from the NAND memory 100 (YES in S202), the memory controller 200 acquires the elapsed time from programming of the target data and the number of executed program operations as history information (S203 and S204). The memory controller 200 then sets a voltage value corresponding to the acquired history information as the determination voltage and retries or re-executes reading of the target data (S205 and S206).

This improves the possibility of acquiring correct data in a single retry read operation in comparison with the comparative method. In other words, the first embodiment enables prevention of the degradation of performance due to an increase in the number of retries of the read operation.

Moreover, according to the first embodiment, the RAM 202 stores the determination-voltage information 206 for defining the relationship among the elapsed time from data programming into a memory cell transistor, the number of executed program operations to the memory cell transistor, and the determination voltage. The memory controller 200 refers to the determination-voltage information 206.

Thereby, The memory controller 200 can acquire a new set value of the determination voltage.

According to the first embodiment, the memory controller 200 acquires the elapsed time from the data programming on the basis of a timestamp, and acquire a new set value of the determination voltage corresponding to the acquired elapsed time, referring to the determination-voltage information 206.

This makes it possible to shift the determination voltage in response to a change in the threshold voltage arising from the data retention characteristics.

Moreover, according to the first embodiment, when programming user data into a word line (S106), the memory controller 200 records a timestamp (S107).

This makes it possible to shift the determination voltage in accordance with the data retention characteristics.

In the above, the memory controller 200 records a timestamp after programming user data into a word line. The order of programming user data into a word line and recording a timestamp is not limited thereto. For example, the memory controller 200 may record a timestamp before (for example, immediately before) programming user data into a word line.

Moreover, according to the first embodiment, the memory controller 200 programs user data in TLC mode, and a timestamp in SLC mode. The TLC mode is a mode in which three-bit data is programmed into each memory cell. The SLC mode is a mode in which one-bit data is programmed into each memory cell.

The SLC mode works to improve tolerance, that is, data reliability to a variation in the threshold voltage as compared with the TLC mode. Hence, with a large variation in the threshold voltage to such an extent that requires the retry read operation, the memory controller 200 can correctly read a timestamp.

The mode selection for each programming is not limited to the above example as long as the timestamp programing mode is smaller in terms of the number of bits of data to be programmed into each memory cell than the user-data programming mode.

For example, user data may be programmed in quad level cell (QLC) mode in which four-bit data is programmed into each memory cell, while timestamps may be programmed in multi-level cell (MLC) mode in which two-bit data is programmed into each memory cell.

Moreover, the memory controller 200 executes the erase operation onto the target block (S103), and programs program-count information into the target block. The memory controller 200 acquires the program-count information from the target block in the retry read operation (S203).

Thereby, the number of executed program operations is counted and recorded.

When programming the target data into a word line including a memory cell being a programming destination (S106), the memory controller 200 records a timestamp (S107). The memory controller 200 then acquires the elapsed time on the basis of the timestamp (S204).

This makes it possible to individually shift the determination voltages for the respective word lines in accordance with the data retention characteristics.

A timestamp may not be recorded per word line. A timestamp may be recorded per set of memory cells. For example, a timestamp may be recorded per set of word lines or per block.

Moreover, according to the first embodiment, the memory controller 200 programs program-count information and a timestamp into a certain word line of the word lines of the target block. For example, in the example of FIG. 8, program-count information and timestamps are programmed into the top word line of the target block.

This can facilitate the management of the correspondence among each memory cell and program-count information and locations of programmed timestamps as to the memory cell.

According to the first embodiment, the memory controller 200 programs user data in TCL mode, and program-count information and a timestamp in SLC mode.

Thereby, with a large variation in the threshold voltage to such an extent that requires the retry read operation, it becomes possible to correctly read program-count information and timestamps.

Assume mode A in which program-count information and a timestamp are programmed, and mode B in which user data is programmed. The mode selection for each programming is not limited to the above selecting method as long as the mode A is smaller in terms of the number of bits of data to be programmed into each memory cell than the mode B.

### Second Embodiment

The first embodiment has escribed the example of determining a new set value of the determination voltage on the basis of the elapsed time from the execution of the program operation and the number of executed program operations. Information for determining a new set value of the determination voltage is not limited to the elapsed time from the execution of the program operation and the number of executed program operations.

A second embodiment will describe an example of determining a new set value of the determination voltage on the basis of the elapsed time from the execution of the program operation, the number of executed program operations, and the location of a memory cell concerned.

The memory cell array 111 having such a three-dimensional configuration as illustrated in FIGS. 2 to 4, for example, is manufactured as follows. Firstly, a large number of wiring layers 11, 12, and 13 are laminated. Then, a hole penetrating the wiring layers 11, 12, and 13 is formed by dry etching to form, for example, the pillar-shaped conductor 14 in the hole.

It is difficult to form the hole in constant diameter at any location along the depth. The hole is likely to increase or decrease in diameter depending on, for example, the location along the depth. This may cause differences in the characteristics of the memory cells according to the location along the depth, that is, the location of a word line.

In the second embodiment, the memory controller 200 acquires a new set value of the determination voltage on the basis of the elapsed time from the execution of the program operation, the number of executed program operations, and the location of a word line in which user data to be read is stored.

FIG. 12 is a diagram illustrating an exemplary configuration of determination-voltage information 206a of the second embodiment. The determination-voltage information 206a is stored in, for example, the RAM 202 as in the first embodiment. In the second embodiment, the determination-voltage information 206a represents information that defines the relationship among the elapsed time, the number of executed program operations, the location of a word line, and the determination voltage.

As an example, the determination-voltage information 206a includes first determination-voltage information 207a that defines a reference value of the determination voltage from the elapsed time and the number of executed program operations on the basis of the relationship illustrated in FIG. 9, and second determination-voltage information 207b that defines an offset from the reference value for each location of a word line.

The data structure of the second determination-voltage information 207b is not limited to a specific structure. The second determination-voltage information 207b may be a table where an offset value is recorded for the location of each word line, or may be a mathematical formula for computing an offset value from the location of a word line. The second determination-voltage information 207b may be used in common among the blocks, or may be prepared for each block.

The memory controller 200 acquires a reference value from the history information (the number of executed program operations and a timestamp) and the first determination-voltage information 207a, and acquires an offset value from the location of a word line (for example, a physical address) and the second determination-voltage information 207b. The memory controller 200 then adds or subtracts the offset value to or from the reference value to be able to acquire a new set value of the determination voltage.

The configuration of the determination-voltage information 206a is not limited thereto. The determination-voltage information 206a can be freely configured as long as it is information specifying the relationship among the elapsed time since the execution of the program operation, the number of executed program operations, the location of a word line, and the determination voltage.

The operation of the memory system 1 of the second embodiment is identical to that in the first embodiment, except for acquiring a new set value of the determination voltage from the determination-voltage information 206a. The description thereof is thus omitted.

As described above, according to the second embodiment, the memory controller 200 acquires, as a new set value of the determination voltage, a voltage value corresponding to the elapsed time since programming of the target data, the number of executed program operations, and the location of a word line in which the target data is programmed.

Thereby, the memory controller 200 can acquire a new set value of the determination voltage based on an optimal algorithm for each word line. Even when the memory cell array 111 has a three-dimensional structure, the memory controller 200 improve the possibility of acquiring correct data in a single retry read operation.

According to the second embodiment, the RAM 202 stores the determination-voltage information 200a for defining the relationship among the elapsed time since data programming into a memory cell transistor, the number of executed program operations to the memory cell transistor, the location of a word line, and the determination voltage. The memory controller 200 refers to the determination-voltage information 206a.

Thereby, the memory controller 200 can acquire a new set value of the determination voltage.

The second embodiment has described the example of using the location of a word line to which the target data has been programmed to acquire a new set value of the determination voltage. Location information for use in acquiring a new set value of the determination voltage is not limited to the location of a word line. Such location information may represent the location of a bit line and the location of a memory cell.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A memory system, comprising:
a first memory including a memory cell array and a peripheral circuit, the memory cell array including a first memory cell transistor, the peripheral circuit executing a read operation to acquire, on the basis of a comparison between a threshold voltage of the first memory cell transistor and a determination voltage, first data programmed to the first memory cell transistor;
an error corrector circuit that corrects error in second data, the second data being the first data acquired by the read operation; and
a memory controller that, when the error corrector circuit has failed to correct the error in the second data, acquires first history information, and changes the determination voltage from a first voltage value to a second voltage value in accordance with the first history information to cause the peripheral circuit to re-execute the read operation, the first history information including second history information on an elapsed time from programming of the first data, and third history information on the number of executed program operations to the first memory cell transistor, the first voltage value being a set value resulting in the failure of the error correction of the second data.

2. The memory system according to claim 1, further comprising
a second memory that stores determination-voltage information that defines a relationship among the elapsed time from programming of the first data to the first memory cell transistor, the number of executed program operations to the first memory cell transistor, and the determination voltage, wherein
the memory controller acquires the second voltage value by referring to the determination-voltage information.

3. The memory system according to claim 1, wherein
the memory controller records a timestamp when programming the first data, and acquires the second history information on the basis of the timestamp.

4. The memory system according to claim 3, wherein
the memory cell array comprises a plurality of second memory cell transistors including the first memory cell transistor,
the first memory comprises a plurality of storage areas,
the storage areas are each made of a plurality of third memory cell transistors included in the second memory cell transistors, and
the memory controller records the timestamp when executing a program operation to a first storage area of the storage areas, the first storage area being a storage area including the first memory cell transistor.

5. The memory system according to claim 1, wherein
the memory cell array comprises a plurality of second memory cell transistors including the first memory cell transistor,
the first memory includes a plurality of storage areas,
the storage areas are each made of a plurality of third memory cell transistors included in the second memory cell transistors, and
after an erase operation to a first storage area of the storage areas, the memory controller causes the peripheral circuit to program the third history information into the first storage area, and acquires the third history information from the first storage area, the first storage area being a storage area including the first memory cell transistor.

6. A method for a read operation of a memory system, comprising:
executing a read operation to acquire first data programmed in a first memory cell transistor of a memory cell array of a first memory, on the basis of a comparison between a threshold voltage of the first memory cell transistor and a determination voltage;
correcting error in second data being the first data acquired by the read operation;
when failing to correct the error in the second data, acquiring first history information, the first history information including second history information on an elapsed time from programming of the first data and third history information on the number of executed program operations to the first memory cell transistor; and
changing the determination voltage from a first voltage value to a second voltage value in accordance with the first history information, and re-executing the read operation, the first voltage value being a set value resulting in the failure of the error correction of the second data, the second voltage value corresponding to the third history information.

7. The method for a read operation of a memory system according to claim 6, wherein
the re-executing includes acquiring the second voltage value on the basis of determination-voltage information stored in a second memory, the determination-voltage information that defines a relationship among elapsed time since data is programmed into a memory cell transistor, the number of executed program operations to the memory cell transistor, and the determination voltage.

8. The method for a read operation of a memory system according to claim 6, further comprising:
recording a timestamp when programming the first data; and
acquiring the second history information on the basis of the timestamp.

9. The method for a read operation of a memory system according to claim 8, wherein
the memory cell array comprises a plurality of second memory cell transistors including the first memory cell transistor,
the first memory comprises a plurality of storage areas,
each of the storage areas is made of a plurality of third memory cell transistors included in the second memory cell transistors, and
the recording includes recording the timestamp upon executing a program operation to a first storage area of the storage areas, the first storage area being a storage area including the first memory cell transistor.

10. The method for a read operation of a memory system according to claim 6, wherein
the memory cell array includes a plurality of second memory cell transistors including the first memory cell transistor,
the first memory includes a plurality of storage areas,
each of the storage areas is made of a plurality of third memory cell transistors included in the second memory cell transistors, the method further comprising:
after an erase operation to a first storage area of the storage areas, programming the third history information into a first storage area, the first storage area being a storage area including the first memory cell transistor, and
acquiring the third history information from the first storage area.
